(19) United States
(12) Patent Application Publication
(10) Pub. No.: US 2026/0117416 A1
(43) Pub. Date: Apr. 30, 2026

(54) Process for Depositing Scandium Nitride by Atomic Layer Deposition Techniques

(71) Applicant: Kurt J. Lesker Company, Jefferson Hills, PA (US)

(72) Inventors: Gilbert Bruce Rayner, JR., Spring Mills, PA (US); Noel Christopher O'Toole, Aliquippa, PA (US)

(21) Appl. No.: 19/371,432

(22) Filed: Oct. 28, 2025

Related U.S. Application Data
(60) Provisional application No. 63/713,213, filed on Oct. 29, 2024.

(51) Int. Cl. C30B 25/16; C23C 16/34; C23C 16/455; C23C 16/50; C30B 25/10; C30B 29/38; H01L 21/02

(52) U.S. Cl. CPC C30B 25/165; C23C 16/34; C23C 16/45527; C23C 16/45542; C23C 16/50; C30B 25/10; C30B 29/38; H10P 14/24; H10P 14/3402

(57) ABSTRACT

A method of forming a film on a surface of a substrate in an internal volume of a reactor is provided. The method includes: dosing the surface of the substrate with a scandium precursor; purging the scandium precursor from the internal volume of the reactor, dosing the surface of the substrate with a co-reactant; and purging the co-reactant from the internal volume of the reactor.

### CROSS REFERENCE TO RELATED APPLICATIONS

This application claims the benefit of U.S. Provisional Patent Application No. 63/713,213, filed Oct. 29, 2024, the disclosure of which is hereby incorporated by reference in its entirety.

### BACKGROUND OF THE INVENTION

### Field of the Invention

The present application is directed to methods and apparatuses for atomic layer deposition, and particularly, methods and apparatuses for depositing scandium nitride by atomic layer deposition techniques.

### Description of Related Art

Scandium nitride (ScN) is a group 3, transition-metal nitride semiconductor that adopts a cubic rock salt crystal structure in its stable phase. Computational analysis of the electronic structure for intrinsic ScN has predicted an indirect band gap at 0.79-0.92 eV (Γ-X) as well as direct band gaps at 1.91-2.02 eV (X point) and 3.58-3.75 eV (Γ point). Experimentally, the low energy direct band gap (X point), for nominally undoped epitaxial ScN with very low impurity levels, was measured at 2.06 eV. The reported values in the literature, however, vary substantially between 2.06-3.1 eV, where impurity levels have been shown to be a primary source of this variation. ScN has received considerable attention for its potential use in thermoelectric applications, and as an interlayer for epitaxial GaN growth.

ScN is commercially relevant primarily because it forms a solid solution with aluminum nitride (AlN), forming aluminum scandium nitride (Al₁₋ₓScₓN), which yields greatly enhanced effective coupling factor (K²) compared to undoped AlN and demonstrates ferroelectric switching at high electric fields. The d₃₃ piezoelectric charge constant of Al₁₋ₓScₓN increases with increased Sc content until x=0.43, where larger concentrations of Sc cause phase segregation or formation of a metastable non-piezoelectric cubic phase. Both AlN and Al₁₋ₓScₓN have been successfully integrated into bulk acoustic wave (BAW) devices, such as film bulk acoustic resonators (FBAR), and derivative technology for radio frequency (RF) filters. Additional applications of Al₁₋ₓScₓN include piezoelectric actuators for microelectromechanical systems (MEMS), piezoelectric micromachined ultrasound transducers (PMUTs), ferroelectric random-access memory (FeRAM), and high operating temperature non-volatile memory (HOT-NVM).

Al₁₋ₓScₓN thin films are traditionally deposited via reactive magnetron sputtering, which yields highly c-axis oriented columnar grains with sufficient process optimization and a compatible substrate. However, sputtering is not suitable for coating high aspect ratio (HAR), vertically layered structures such as those desired for use in 3D embedded memory. HAR structures may also be utilized in 3D piezoelectric MEMS (piezoMEMS) for emerging high-performance actuator applications.

Therefore, an improved method for forming films comprising scandium is desirable. Additionally, an atomic layer deposition apparatus that can form films comprising scandium is also desirable.

### SUMMARY OF THE INVENTION

In view of the foregoing, there is a current need in the art for a method of forming a film on the surface of a substrate. In further view of the foregoing, there is a current need in the art for an atomic layer deposition apparatus that can form a film on the surface of a substrate.

In one non-limiting example of the present disclosure, a method of forming a film on a surface of a substrate in an internal volume of a reactor includes: dosing the surface of the substrate with a scandium precursor; purging the scandium precursor from the internal volume of the reactor; dosing the surface of the substrate with a co-reactant; and purging the co-reactant from the internal volume of the reactor.

The co-reactant may be plasma including N₂, H₂, NH₃, N₂H₄, Ar, or a mixture thereof. The co-reactant may be ammonia (NH₃), hydrazine (N₂H₄), or a mixture thereof. The scandium precursor may include Sc(Cp)₃, Sc(EtCp)₃, Sc(MeCp)₃, ScCl₃, CISc(EtCp)₂, CISc(MeCp)₂, (bdma)Sc(EtCp)₂, (dbt)Sc(EtCp)₂, Sc(TMHD)₃ or a combination thereof. The substrate may include silicon, germanium, sapphire, magnesium oxide, boron nitride, aluminum nitride, gallium nitride, or indium nitride, or a combination thereof. The method may further include heating the substrate to a temperature in the range of from 100° C. to 400° C. The method may further include heating the substrate to a temperature in the range of from 200° C. to 215° C. The forming step may include forming a single-crystal, cubic phase scandium nitride film on the surface of the substrate. The forming step may include forming epitaxial cubic phase scandium nitride film on the surface of the substrate. The method may further include positioning the substrate in the internal volume of the reactor under ultra-high purity conditions. The forming step may include forming a scandium nitride film comprises less than 0.5 atom % oxygen content.

In another non-limiting example of the present disclosure, an apparatus for atomic scale processing includes: a reactor having inner and outer surfaces, wherein at least a portion of the inner surfaces define an internal volume of the reactor; a fixture assembly positioned within the internal volume of the reactor having a surface configured to hold a coated substrate within the internal volume of the reactor; a scandium precursor dosage source including a scandium precursor; and a co-reactant dosage source including a co-reactant.

The co-reactant dosage source may be an inductively coupled plasma source. The co-reactant may include plasma including N₂, H₂, NH₃, N₂H₄, Ar, or a mixture thereof. The co-reactant may include ammonia (NH₃), hydrazine (N₂H₄), or a mixture thereof. The scandium precursor may include Sc(Cp)₃, Sc(EtCp)₃, Sc(MeCp)₃, ScCl₃, ClSc(EtCp)₂, ClSc(MeCp)₂, (bdma)Sc(EtCp)₂, (dbt)Sc(EtCp)₂, Sc(TMHD)₃, or a combination thereof. The coated substrate may include: a substrate; and a scandium nitride film over a surface of the substrate. The substrate may include silicon, germanium, sapphire, magnesium oxide, boron nitride, aluminum nitride, gallium nitride, indium nitride, or a combination thereof. The scandium nitride film may include single-crystal, cubic phase scandium nitride. The scandium nitride film may include epitaxial, cubic phase scandium nitride. The scandium nitride film may include less than 0.5 atom % oxygen content. The substrate may be heated to a temperature in the range of from 100° C. and 400° C.

Various non-limiting examples of the present disclosure will now be described and set forth in the following numbered clauses.

Clause 1: A method of forming a film on a surface of a substrate in an internal volume of a reactor, comprising: dosing the surface of the substrate with a scandium precursor; purging the scandium precursor from the internal volume of the reactor; dosing the surface of the substrate with a co-reactant; and purging the co-reactant from the internal volume of the reactor.

Clause 2: The method of clause 1, wherein the co-reactant is plasma comprising N₂, H₂, NH₃, N₂H₄, Ar, or a mixture thereof.

Clause 3: The method of clause 1, wherein the co-reactant is ammonia (NH₃), hydrazine (N₂H₄), or a mixture thereof.

Clause 4: The method of any one of clauses 1-3, wherein the scandium precursor comprises Sc(Cp)₃, Sc(EtCp)₃, Sc(MeCp)₃, ScCl₃, CISc(EtCp)₂, ClSc(MeCp)₂, (bdma)Sc(EtCp)₂, (dbt)Sc(EtCp)₂, Sc(TMHD)₃, or a combination thereof.

Clause 5: The method of any one of clauses 1-4, wherein the substrate comprises silicon, germanium, sapphire, magnesium oxide, boron nitride, aluminum nitride, gallium nitride, or indium nitride, or a combination thereof.

Clause 6: The method of any one of clauses 1-5, further comprising heating the substrate to a temperature in the range of from 100° C. to 400° C.

Clause 7: The method of any one of clauses 1-6, further comprising heating the substrate to a temperature in the range of from 200° C. to 215° C.

Clause 8: The method of any of clauses 1-7, wherein the forming step comprises forming a single-crystal, cubic phase scandium nitride film on the surface of the substrate.

Clause 9: The method of any one of clauses 1-8, wherein the forming step comprises forming epitaxial cubic phase scandium nitride film on the surface of the substrate.

Clause 10: The method of any one of clauses 1-9, further comprising positioning the substrate in the internal volume of the reactor under ultra-high purity conditions.

Clause 11: The method of any one of clauses 1-10, wherein the forming step comprises forming a scandium nitride film comprises less than 0.5 atom % oxygen content.

Clause 12: An apparatus for atomic scale processing, comprising: a reactor having inner and outer surfaces, wherein at least a portion of the inner surfaces define an internal volume of the reactor; a fixture assembly positioned within the internal volume of the reactor having a surface configured to hold a coated substrate within the internal volume of the reactor; a scandium precursor dosage source comprising a scandium precursor; and a co-reactant dosage source comprising a co-reactant.

Clause 13: The apparatus of clause 12, wherein the co-reactant dosage source is an inductively coupled plasma source.

Clause 14: The apparatus of clause 12 or clause 13, wherein the co-reactant comprises plasma comprising N₂, H₂, NH₃, N₂H₄, Ar, or a mixture thereof.

Clause 15: The apparatus of clause 12, wherein the co-reactant comprises ammonia (NH₃), hydrazine (N₂H₄), or a mixture thereof.

Clause 16: The apparatus of any one of clauses 12-15, wherein the scandium precursor comprises Sc(Cp)₃, Sc(EtCp)₃, Sc(MeCp)₃, ScCl₃, CISc(EtCp)₂, ClSc(MeCp)₂, (bdma)Sc(EtCp)₂, (dbt)Sc(EtCp)₂, Sc(TMHD)₃, or a combination thereof.

Clause 17: The apparatus of any one of clauses 12-16, wherein the coated substrate comprises: a substrate; and a scandium nitride film over a surface of the substrate.

Clause 18: The apparatus of clause 17, wherein the substrate comprises silicon, germanium, sapphire, magnesium oxide, boron nitride, aluminum nitride, gallium nitride, indium nitride, or a combination thereof.

Clause 19: The apparatus of clause 17, wherein the scandium nitride film comprises single-crystal, cubic phase scandium nitride.

Clause 20: The apparatus of clause 17, wherein the scandium nitride film comprises epitaxial, cubic phase scandium nitride.

Clause 21: The apparatus of any one of clauses 17-20, wherein the scandium nitride film comprises less than 0.5 atom % oxygen content.

Clause 22: The apparatus of any one of clauses 12-21, wherein the substrate is heated to a temperature in the range of from 100° C. and 400° C.

### BRIEF DESCRIPTION OF THE DRAWINGS

FIG. 1 is a cross-sectional view of a reactor for atomic scale processing according to one aspect of the present disclosure;

FIG. 2 is a cross-sectional view of an inductively coupled plasma source according to another aspect of the present disclosure;

FIG. 3 is a perspective view of an apparatus for atomic scale processing according to another aspect of the present disclosure;

FIG. 4 is a perspective view of an apparatus for atomic scale processing according to another aspect of the present disclosure;

FIG. 5A is a perspective view of a precursor/reactant vapor delivery arrangement according to another aspect of the present disclosure;

FIG. 5B is a perspective view of a precursor/reactant vapor delivery arrangement according to another aspect of the present disclosure;

FIG. 5C is a schematic of an mass flow controller (MFC) arrangement for implementing with any of the precursor/reactant vapor delivery arrangements disclosed herein according to another aspect of the present disclosure;

FIG. 6 is a diagram of a method according to another aspect of the present disclosure;

FIG. 7A is a graph of ScN thickness vs. time measured in real-time by multiwavelength ellipsometry (MWE) during growth for a series of 30 PEALD cycles;

FIG. 7B is a graph of a 30-cycle growth profile of ScN thickness vs. time measured in real-time by multiwavelength ellipsometry (MWE) during growth;

FIG. 7C is a graph of the general features of the PEALD ScN step profile of ScN thickness vs. time measured in real-time by multiwavelength ellipsometry (MWE) during growth;

FIG. 8A is a graph of ScN growth-per-cycle (GPC) vs. ClSc(EtCp)₂ dose time at substrate temperatures ranging from 200-300° C.;

FIG. 8B is a graph of ScN growth-per-cycle (GPC) vs. N₂—H₂ plasma dose time at 215° C. substrate temperature;

FIG. 8C is a graph of ScN growth-per-cycle (GPC) vs. substrate temperature;

FIG. 9A is a graph of ScN growth-per-cycle (GPC) average & GPC at the center of the substrate vs. N₂—H₂ plasma dose time at 215° C. substrate temperature;

FIG. 9B is a graph of ScN growth-per-cycle (GPC) average & thickness non-uniformity (NU) vs. N₂—H₂ plasma dose time at 215° C. substrate temperature;

FIG. 10A is a graph of ScN growth-per-cycle (GPC) vs. CISc(EtCp)₂ dose time at 215° C. substrate temperature before and after thermally cycling the Sc precursor between room temperature and 180° C.;

FIG. 10B is a graph of ScN growth-per-cycle (GPC) vs. CISc(EtCp)₂ purge time;

FIG. 10C is a graph of ScN growth-per-cycle (GPC) vs. N₂—H₂ plasma purge time;

FIG. 10D is a graph of ScN growth-per-cycle (GPC) vs. CISc(EtCp)₂ dose and purge times;

FIG. 11A is a graph of ellipsometric data for thin and thick ScN films at the center and edge of the wafer;

FIG. 11B is a graph of ScN optical constants determined at the center and edge positions of 150 mm Si substrates;

FIG. 12 is a graph of a x-ray photoelectron spectroscopy (XPS) depth profile for ScN showing the concentration vs. sputter depth of all major and minor elemental components of the film;

FIG. 13A is a graph of grazing incidence x-ray diffraction (GIXRD) patterns for ScN on 150 mm Si (100) at center and edge positions;

FIG. 13B is a graph of grazing incidence x-ray diffraction (GIXRD) patterns for ScN on Al₂O₃ (0001);

FIG. 13C is a graph of grazing incidence x-ray diffraction (GIXRD) patterns for ScN on MgO (001);

FIG. 14 is a graph of grazing incidence x-ray diffraction (GIXRD) patterns for ScN #2 measured at the center of the 150 mm Si (100) substrate;

FIG. 15 is a graph of x-ray diffraction (XRD) interference patterns observed for the ScN (111) peak measured on c-plane α-Al₂O₃ substrate;

FIG. 16A are graphs of phi-scans for ScN on Al₂O₃ (0001);

FIG. 16B are graphs of phi-scans for ScN on MgO (001);

FIG. 17A is a field emission scanning electron microscopy (FESEM) image of a top view of ScN #2;

FIG. 17B is a field emission scanning electron microscopy (FESEM) image of a cross-sectional view of ScN #2;

FIG. 17C is an image of ScN-coated trenches with a 4:1 aspect ratio imaged by field emission scanning electron microscopy (FESEM); and

FIG. 17D is an image of a cross-sectional view of ScN-coated trenches with 4:1 aspect ratio imaged by field emission scanning electron microscopy (FESEM).

### DESCRIPTION OF THE INVENTION

For purposes of the description hereinafter, spatial orientation terms, as used, shall relate to the referenced embodiment as it is oriented in the accompanying drawings, figures, or otherwise described in the following detailed description. However, it is to be understood that the embodiments described hereinafter may assume many alternative variations and configurations. It is also to be understood that the specific components, devices, features, and operational sequences illustrated in the accompanying drawings, figures, or otherwise described herein are simply exemplary and should not be considered as limiting.

For purposes of the description hereinafter, the terms “upper,” “lower,” “right,” “left,” “vertical,” “horizontal,” “top,” “bottom,” “lateral,” “longitudinal,” and derivatives thereof shall relate to the invention as it is oriented in the drawing figures. However, it is to be understood that the invention may assume alternative variations and step sequences, except where expressly specified to the contrary. It is also to be understood that the specific devices and processes illustrated in the attached drawings, and described in the following specification, are simply exemplary embodiments of the invention. Hence, specific dimensions and other physical characteristics related to the embodiments disclosed herein are not to be considered as limiting.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

In this application, the use of the singular includes the plural and plural encompasses singular, unless specifically stated otherwise. In addition, in this application, the use of “or” means “and/or” unless specifically stated otherwise, even though “and/or” may be explicitly used in certain instances. Further, in this application, the use of “a” or “an” means “at least one” unless specifically stated otherwise.

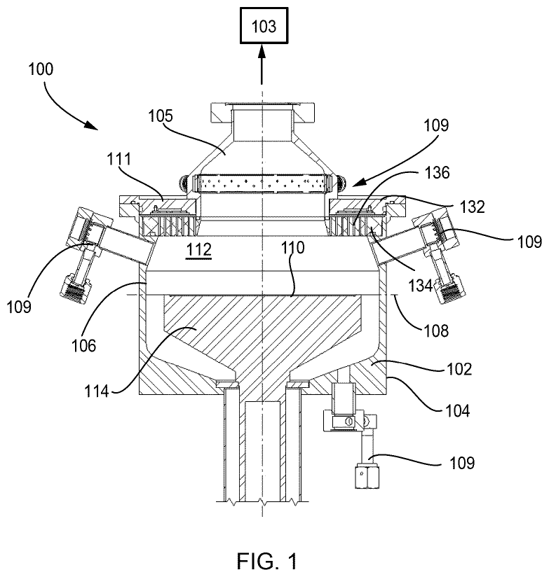

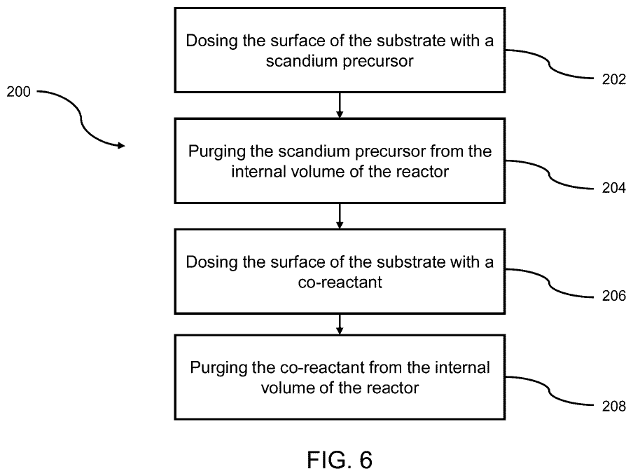

The present disclosure includes a method 200 of forming a film on a surface of a substrate. A non-limiting example of a method 200 of the present disclosure is shown in FIG. 6. The method 200 of forming a film on a surface of a substrate may be performed by an atomic scale processing apparatus 100, such as an ALD apparatus 100. Referring to FIG. 1, the forming a film on a surface of a substrate may be performed with an apparatus 100 for atomic scale processing. As such, the present disclosure also includes an apparatus for atomic scale processing that can form a film on a surface of a substrate. For example, the atomic scale processing apparatus 100 may be an atomic layer deposition apparatus. As used herein, “atomic layer deposition” or “ALD” refers to a chemical vapor deposition (CVD) technique based on sequential, self-limiting surface reactions between gas/vapor phase species and active surface sites. The unique surface-controlled nature of ALD makes it an ideal choice for demanding applications requiring conformal, high-quality oxide and non-oxide based materials, as well as their interfaces. However, there are currently no reports of ALD used to produce scandium films because there are no current techniques capable of producing scandium films with ALD. During the ALD process, at least two precursors may be pulsed (or dosed) sequentially into a reaction space where the substrate is located. A complete sequence (or cycle) may be made up of a series of pulse (or dose) and purge steps, such as at least 2 pulse and purge steps, or at least 3 pulse and purge steps, or at least 4 pulse and purge steps. A complete ALD cycle is therefore at least four steps, two dosage and two purge steps. Pulse steps are separated by purge steps to remove any remaining precursor and/or volatile reaction byproducts from the internal volume of the reactor between pulses.

Advantages of ALD methods include uniform, conformal surface coverage with atomic scale thickness and composition control. Sequential precursor pulsing (or dosing) eliminates the potential for gas-phase reactions that result in film defects so that highly reactive precursors can be utilized. Highly reactive precursors yield dense, continuous films with low levels of residual contamination and defects at relatively low process temperatures.

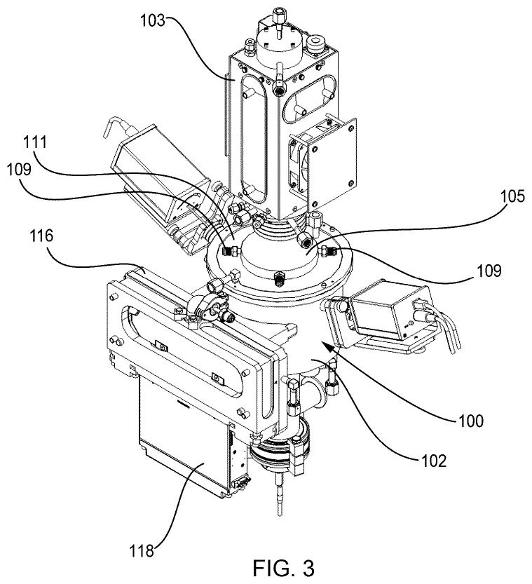

The method 200 may be performed in an atomic scale processing apparatus, such as an ALD apparatus 100. The apparatus may include a reactor 102. The reactor 102 may comprise outer surfaces 104 and inner surfaces 106. The inner surfaces 106 of the reactor 102 above the plane 108 of a substrate 110 defines an internal volume 112 of the reactor 102. A fixture assembly 114 may be within the internal volume 112. The fixture assembly 114 may have a surface configured to hold a substrate 110 within the internal volume 112 of the reactor 102. A transfer port 116 may be in communication with the reactor 102 and located at the front of the reactor 102, as shown in FIG. 3. A gate valve 118 may be in communication with the transfer port 116 and is configured to isolate the reactor 102.

The apparatus 100 geometry has a generally cylindrical symmetry, where the central axis is oriented vertically and perpendicular to the planar, circular surface of the fixture assembly 114. The central axis of the apparatus 100 passes through the origin of the fixture assembly 114 surface, and the fixture assembly 114 may include an embedded heating element for active heating of the substrate 110. The top surface of the fixture assembly 114 faces upward toward the top of the apparatus 100.

Multiple gas injection ports 109 are configured to facilitate the introduction of gas and/or vapor into the apparatus 100. As discussed hereinafter, the gas injection ports 109 may have the exclusive function of injecting gas into the apparatus 100, or may have multiple features associated therewith. For example, while some of the gas injection ports 109 may still serve to facilitate the introduction of gas into the apparatus 100, certain of the ports 109 may be used for viewing the internal volume 112 of the reactor 102, or otherwise directly or indirectly interacting with the internal volume 112 of the reactor 102. The gas injection ports 109 may extend through the outer surface 104 of the reactor 102 in order to introduce gases into the internal volume 112 of the reactor 102. The gas injection ports 109 may be configured to inject a gas, such as inactive gas, a precursor, and/or a co-reactant, into the internal volume 112 of the reactor 102.

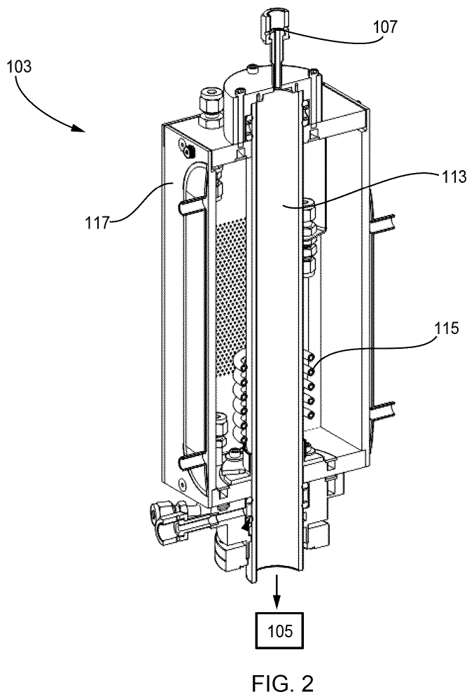

ALD techniques include purely thermal and plasma enhanced ALD (PEALD). In some non-limiting embodiments, the film is formed by PEALD, and the reactor 102 includes an inductively-coupled plasma (ICP) source 103, as shown in FIG. 2. The ICP source 103 may be coupled to a gas injection port 109, such as a plasma port 105. The ICP source 103 may be in communication with the reactor 102 and located above the reactor 102. The ICP source 103 may be configured to introduce (dose) plasma species into the internal volume 112 of the reactor 102. The ICP source 103 may include a cylindrical dielectric tube 113 where the axis of the tube is in-line with central axis of the apparatus 100. An ex-situ electrode 115 may form a helix around the dielectric tube for plasma generation. An enclosure 117 may be provided around the electrode 115 and dielectric tube 113 to shield RF radiation produced by the electrode 115, as well as radiation emitted by plasma species generated inside the dielectric tube 113. The apparatus may include a plasma port 105 for connecting the ICP source 103 with the reactor 102. Gas from the process gas source 107 may be injected into the dielectric tube 113 of the ICP source 103, through the plasma port 105, and into the internal volume 112 of the reactor 102. However, if a plasma port 105 is not used, the lid assembly 111 can be optimized to include performance for thermal ALD processes.

A process gas source 107 may be in direct communication with the ICP source 103, thereby allowing process gas to flow into the dielectric tube 113 of the ICP source 103. A process gas can consist of an inactive gas and/or one or more precursor/plasma gases such as O₂, N₂, H₂, NH₃, and the like. As such, the present ALD method 200 may include injecting a process gas into the ICP source 103.

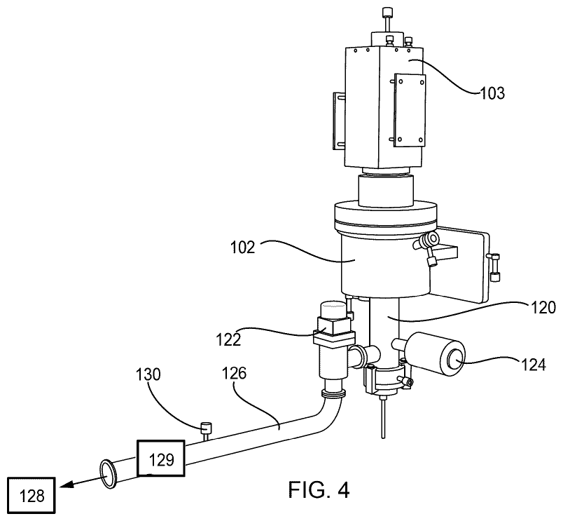

Referring to FIG. 4, an exhaust port 120 may be in communication with the reactor 102 and a pump isolation valve 122. A pressure gauge 124 may be attached to and in communication with the exhaust port 120 leading from the reactor 102. The pressure gauge 124 may be used to determine the pressure in the reactor 102 without introducing dead-space volume inside the reactor 102. A pump isolation valve 122 may be attached to a portion of the exhaust port 120 and a portion of the foreline 126. The pump isolation valve 122 may be opened or closed in order to isolate a pump 128 from the reactor 102. The foreline 126 may run from the reactor 102, to the pump isolation valve 122, and then to the pump 128. The pump 128 may be any suitable chemical series pump (can include mechanical pumps only, or a combination of mechanical and turbomolecular pumps) that enables the flow of process gases, over the required range of pressures and gas flow rates, through the reactor 102 and foreline 126 such that continuous, viscous-laminar flow is maintained. A downstream port 130 may be attached to and in communication with the foreline 126. The downstream port 130 provides purge and vent protection to reduce the potential for pump back-diffusion and back-streaming of impurities. For example, the downstream port 130 may be configured to provide continuous, viscous-laminar gas flow when the reactor 102 is not in communication with the pump 128. Therefore, pump 128 can remain on when the pump isolation valve 122 is closed without the risk of introducing impurities into the foreline 126 from the pump 128. The ALD apparatus 100 may further include a throttle valve 129. The throttle valve 129 may be located on the foreline 126 and may be configured to modify the conductance between the reaction space volume within the internal volume 112 of the reactor 102 and the pump 128. The throttle valve 129 therefore can be used to control the effective pumping speed of the pump 128 to adjust the residence time of species within the internal volume 112 of the reactor 102.

The ALD apparatus 100 may further include a lid assembly 111, in which gas injection ports 109 extend through in order to introduce gases into the internal volume 112 of the reactor 102. The lid assembly 111 can be made from multiple, detachable components for flexibility, as well as to as to simplify manufacturing and serviceability.

The method 200 of forming a film on a surface of a substrate may include forming a film on a surface of any substrate capable of receiving precursor dosage and having a film formed thereover. For example, the substrate 118 may comprise silicon (Si), germanium (Ge), sapphire (Al₂O₃), magnesium oxide (MgO), boron nitride (BN), aluminum nitride (AlN), gallium nitride (GaN), indium nitride (InN), and/or the like. The substrate 118 may be positioned on a surface of a fixture assembly 114 that is positioned within the internal volume 112 of the reactor 102. This allows precursor dosage of the surface of the substrate 118 and formation of the film.

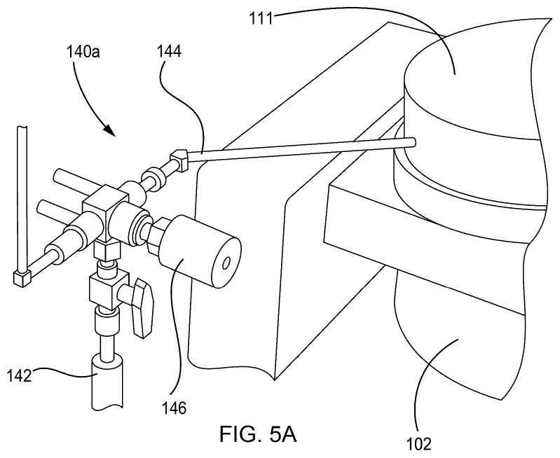

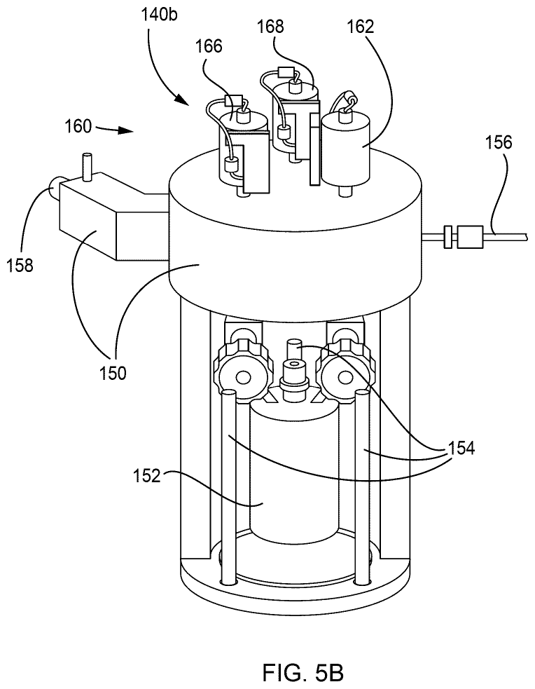

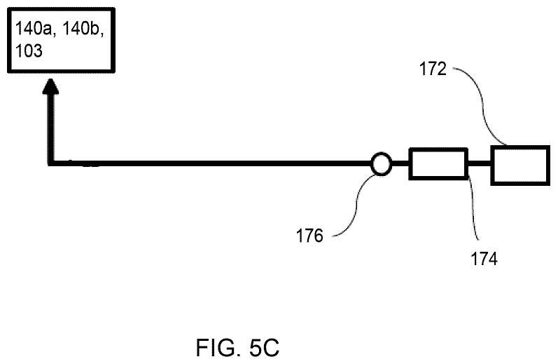

In some non-limiting embodiments, multiple precursor dosage steps (separated by purge steps) are implemented in the ALD process. The method 200 may include providing a continuous flow of inactive gas into the internal volume 112 of the reactor 102. Inactive gas flow may be provided by at least one inactive gas dispersion arrangement 132 that is configured to introduce inactive gas into the internal volume 112 of the reactor 102. The at least one inactive gas dispersion arrangement 132 may be in fluid communication with one or more of the gas injection ports 109. The inactive gas dispersion arrangement 132 may include a primary dispersion member 134 having a thickness and multiple holes 136 extending therethrough. In this manner, at least a portion of the inactive gas introduced into the internal volume 112 of the reactor 102 occurs through one or more of the holes 136. Inactive gas flow provided by at least one inactive gas dispersion arrangement 132 has the benefit of creating a barrier which minimizes interactions between the precursor or co-reactant and the inner surfaces 106 of the reactor 102. Inactive gas flow may also be provided by one or more precursor vapor delivery arrangements 140a-b, an MFC arrangement as shown in FIG. 5C, and/or the process gas source 107.

The method 200 of forming a film on a surface of a substrate includes a step 202 of dosing the surface of the substrate with a first precursor. Dosing 202 may be performed by at least one precursor vapor delivery arrangement 140a-b. A precursor vapor delivery arrangement 140a-b can be used to dose a precursor and/or a co-reactant. In this regard, a precursor dosage source and/or a co-reactant dosage source may be a precursor vapor delivery arrangement 140a-b, or can be an ICP source 103, each of which may include an MFC arrangement. FIG. 5A shows one example of a precursor vapor delivery arrangement 140a, however, any suitable precursor vapor delivery arrangement may be implemented. The at least one precursor vapor delivery arrangement 140a-b may be in communication with the reactor 102, such as in communication with one of the gas injection ports 109. The precursor vapor delivery arrangement 140a may include an ampoule 142 that includes a precursor. A line to the reactor 144 may be in communication with the ampoule 142 and the reactor 102, such as the ampoule 142 and one of the gas injection ports 109, such that the precursor may be transported to the reactor 102. A valve 146 may be attached to and in communication with the line to the reactor 144. The valve 146 may be opened or closed to control the introduction of precursor vapor from the ampoule 142 into the line to the reactor 144. The precursor vapor delivery arrangement 140a may include a mass flow controller which provides continuous, viscous-laminar inactive gas flow through valve 146 and the line to the reactor 144 for effective vapor delivery and subsequent purging of the delivery components.

In some non-limiting embodiments, the precursor vapor delivery arrangement 140a-b may be the precursor vapor delivery arrangement 140b of FIG. 5B and may include a lower oven enclosure to aid in temperature management. The precursor vapor delivery arrangement 140b may include a carrier gas input line 156 that is in communication with a carrier gas source to allow a carrier gas to flow into the precursor vapor delivery arrangement 140b. The precursor vapor delivery arrangement 140b may include a carrier gas output line 158 that is in communication with the reactor 102 to allow carrier gas to flow out of the precursor vapor delivery arrangement 140b and into the reactor 102. The precursor vapor delivery arrangement 140b may include an ampoule 152 that includes a liquid or solid phase precursor. The precursor vapor delivery arrangement 140b may include a valve manifold 160. The valve manifold 160 may include an input valve 162 that may be open or closed. When the input valve 162 is open, the input valve 162 allows the carrier gas from the carrier gas input line 156 to flow into the ampoule 152. When the input valve 162 is closed, the input valve 162 prevents the carrier gas from entering the ampoule 152. The valve manifold 160 may include an output valve 166 that may be open or closed. When the output valve 166 is open, the output valve 166 allows the carrier gas present in the ampoule 152 to flow out of the ampoule 152 and into the carrier gas output line 158. When the output valve 166 is closed, the output valve 166 prevents the carrier gas from exiting the ampoule 152. The valve manifold 160 may include a bypass valve 168 that may be open or closed. When the bypass valve 168 is open, the bypass valve 168 allows the carrier gas to flow from the carrier gas input line 156 to the carrier gas output line 158 without entering the ampoule 152.

When dosing of a precursor to the reactor 102 is not needed, the input valve 162 and the output valve 166 may be closed and the bypass valve 168 may be open such that the carrier gas cannot flow to the ampoule 152 to pick up the precursor vapor in the ampoule 152, but instead, the carrier gas flows from the carrier gas input line 156 to the bypass valve 168 and then to the carrier gas output line 158. The carrier gas flow rate may be from approximately 10 to 100 standard cubic centimeters per minute (sccm). When precursor dosing is needed, the bypass valve 168 is closed and the input valve 162 and the output valve 166 are opened simultaneously. This configuration allows the carrier gas to flow from the carrier gas input line 156, into the ampoule 152 where the carrier gas picks up the precursor vapor therein, and then the carrier gas with the precursor vapor flow into the carrier gas output line 158 which transports the carrier gas and the precursor vapor to the reactor 102. Alternatively, during precursor dosing, the bypass valve 168 may be closed and only the input valve 162 may be opened, simultaneously or with a programmed delay, leaving the output valve 166 closed. This configuration allows carrier gas to flow from the carrier gas input line 156 to the ampoule 152 without letting the carrier gas exit the ampoule 152 to the carrier gas output line 158. This valve configuration allows for pressure in the ampoule 152 head-space to increase, such as an increase to 10-20 Torr inside the ampoule 152, compared to the approximate pressure inside the reactor 102 of 1 Torr. Once a sufficient pressure increase in the ampoule 152 is achieved, the output valve 166 may be opened, thereby allowing the carrier gas with precursor vapor to flow into the carrier has output line 158 and then to the reactor 102. The increased pressure inside the ampoule 152 head-space from the output valve 166 being closed allows for the carrier gas and precursor vapor to be more easily distributed inside the reactor 102 and across the substrate 110. When dosing is completed, the bypass valve 168 may be opened and the input valve 162 and the output valve 166 may be closed, simultaneously or with a programmed delay, thus allowing the carrier gas to flow from the carrier gas input line 156, to the bypass valve 168, and then to the carrier gas output line 158, thereby avoiding the ampoule 152 to prevent dosing and enable purging for the delivery channel. The precursor vapor delivery arrangement 140b may include one or more independently controlled heat zones to aid in temperature management. For example, the precursor vapor delivery arrangement 140b may include a first independently controlled heat zone at the ampoule 152. The precursor vapor delivery arrangement 140b may include a second independently controlled heat zone at the valve manifold 160. The precursor vapor delivery arrangement 140b may include a third independently controlled heat zone around the carrier gas output line 158. The precursor vapor delivery arrangement 140b may also include a mass flow controller (MFC), such as the MFC arrangement in FIG. 5C, located upstream from the valve manifold 160, which provides continuous, viscous-laminar inactive gas flow through the valve manifold 160 and the carrier gas output line 158 for effective vapor delivery and subsequent purging of the delivery components.

The lower oven enclosure may include a heater jacket 150, or some other suitable means of supplying thermal energy, around at least a portion of an ampoule 152. In some non-limiting embodiments, the heater jacket 150, or some other suitable means of supplying thermal energy, may be provided around the entire circumference of the ampoule 152. The lower oven enclosure may include at least two heater cartridges 154, such as two heater cartridges 154, spaced squally apart from each other, between the ampoule 152 and the heater jacket 150. For example, the lower oven enclosure may include at least three heater cartridges 154, such as three heater cartridges 154, spaced equally apart from each other between the ampoule 152 and the heater jacket 150.

As shown in FIG. 5C, a mass flow controller (MFC) arrangement may be provided. The MFC arrangement may be provided that may be implemented upstream from any precursor vapor or gas delivery arrangements, such as the precursor vapor delivery arrangement 140a-b disclosed herein, or the ICP source 103 disclosed herein. For example, the MFC arrangement of FIG. 5C may be implemented upstream from the ICP source 103 of FIG. 2, the precursor vapor delivery arrangement 140a of FIG. 5A, and/or the precursor vapor delivery arrangement 140b of FIG. 5B. more than one MFC arrangement may be present if multiple process gases are desired. For example, at least one MFC arrangement, or at least two MFC arrangements, or at least three MFC arrangements, each containing the same or different gases, may be implemented upstream from the precursor vapor delivery arrangement 140a-b or the ICP source 103. An MFC arrangement includes a gas source 172. For example, the gas source 172 may be an inactive gas source and may contain Ar or N₂. In another example, the gas source 172 may be a reactant gas source and may contain NH₃, H₂, O₂, and the like. In another example, the gas source 172 may be a reactant plasma gas source and may contain NH₃, H₂, O₂, N₂ and the like, and may provide reactant gas flow through the ICP source 103. An MFC 174 may be in communication with the gas source 172. The MFC 174 may be used to control the continuous flow of gas through the precursor vapor delivery arrangement 140a-b or ICP source 103. Continuous, viscous-laminar inactive gas flow serves as a carrier gas during precursor delivery/dose steps, and as a purge gas during subsequent purge steps. This inactive gas flow also creates a diffusion barrier to prevent unwanted back-diffusion of downstream impurities into the vapor delivery channel. The MFC arrangement further includes a valve 176 that may be open or closed to allow or prevent gas flow to the precursor vapor delivery arrangement 140a-b or to the ICP source 103. The valve 176 is in communication with both the MFC 174 and the precursor vapor delivery arrangement 140a-b or ICP source 103.

In some non-limiting embodiments, the method 200 of forming a film on a surface of a substrate includes the step 202 of dosing the surface of the substrate with a first precursor for at least 0.01 s, or at least 1 s, or at least 2 s, or at least 3 s, or at least 4 s, or at least 5 s, or at least 6 s, or at least 10 s, or at least 15 s, or at least 20 s, or at least 25 s. The method 200 of forming a film on a surface of a substrate includes the step 202 of dosing the surface of the substrate with a first precursor for up to 25 s, or up to 20 s, or up to 15 s, or up to 10 s. The time of dosage of the first precursor and co-reactant is determined based on how long the valve 146 of the precursor vapor delivery arrangement 140a or the valve manifold 160 of the precursor vapor delivery arrangement 140b (i.e., the input valve 162 and the output valve 166) is open and/or the valve 176 on the MFC arrangement is open, if present.

In some non-limiting embodiments, the method 200 may include heating the surface of the substrate 118 in the internal volume 112 of the reactor 102. The surface of the substrate may be heated to a temperature of at least 100° C., or at least 125° C., or at least 150° C., or at least 175° C., or at least 200° C. The surface of the substrate may be heated to a temperature of up to 400° C., or up to 350° C., or up to 300° C., or up to 250° C., or up to 225° C., or up to 215° C. The surface of the substrate may be heated to a temperature in the range of from 100° C. to 400° C., or in the range of from 125° C. to 350° C., or in the range of from 150° C. to 300° C., or in the range of from 175° C. to 250° C., or in the range of from 200° C. to 225° C., or in the range of from 200° C. to 215° C.

In some non-limiting embodiments, the method 200 of forming a film on the surface of the substrate may include forming the film under ultra-high purity (UHP) conditions. As used herein, “ultra-high purity conditions” refer to an impurity partial pressure inside the internal volume 112 of the reactor 102 being less than 10⁻⁶ Torr. Common impurities include O₂, H₂O, carbon monoxide (CO), carbon dioxide (CO₂). UHP conditions may be established according to the methods and apparatuses disclosed in U.S. Pat. No. 11,621,571, the disclosure of which is hereby incorporated by reference in its entirety. UHP conditions may limit the role of background impurities during atomic scale processing, such as ALD, for example, to limit the incorporation of background oxygen impurities into films.

UHP conditions are based on reduced levels of background impurities to limit their role in surface reactions before, during, and after film growth and/or etch by atomic scale processing techniques, such as limiting the incorporation of background oxygen impurities in nitride thin films. UHP conditions are also important in surface engineering where extremely tight control over the surface composition is paramount. For example, preparation of III-V materials (e.g., BN, AlN, GaN and InN), as well as other non-silicon based, semiconductor channel materials (including 2D materials) for subsequent high-k gate integration. Establishing UHP conditions are also important for ALD/PEALD of elemental metals such as Ti, Al, Ta, and the like, where, similar to nitrides, lowering oxygen content is extremely important. Since most transition and p-block metals tend to readily oxidize, this presents some significant equipment design challenges that require careful consideration in order to reduce exposure to background impurities, such as oxygen species before, during, and after film growth.

To establish a UHP process environment inside the reactor 102, the partial pressure of background impurities must be reduced to less than 10⁻⁶ Torr (i.e., less than one Langmuir, or monolayer equivalent, exposure every second). Since water vapor is a very common and problematic background impurity for the growth of non-oxide based materials, it is used here to establish the upper limit (i.e., 10⁻⁶ Torr partial pressure) for defining UHP process conditions. To establish this requirement, it is instructive to first consider the specifications for a UHP grade (99.999% purity) process gas such as Ar and N₂. UHP grade Ar/N₂ contains oxygen impurities up to the ppm level. As discussed previously, these impurities include O₂, H₂O, CO and CO₂. For Ar/N₂ at 1 Torr pressure, the ppm level corresponds to 10⁻⁶ Torr partial pressure. For an impurity such as H₂O at 10⁻⁶ Torr partial pressure, a growing nitride surface experiences 1 Langmuir H₂O exposure every second (1 Langmuir=10⁻⁶ Torr s). Under these conditions, if each H₂O molecule striking the surface adsorbs (or sticks), then ˜1 monolayer surface coverage every second would be subsequently obtained. A typical PEALD process deposits less than a monolayer of material per each complete cycle (one complete cycle=one full sequence of precursor dose and purge steps). Typical PEALD cycle times range from approximately 10⁻⁶⁰ seconds. Therefore, each sub-monolayer of material deposited experiences 10-60 Langmuir exposures (or 10-60 monolayer equivalent exposures) from water vapor at the 10⁻⁶ Torr level every second.

In some non-limiting embodiments, the first precursor comprises scandium, such as a scandium precursor. The scandium precursor may comprise tris(cyclopentadienyl) scandium (Sc(Cp)₃), tris(ethylcyclopentadienyl) scandium (Sc(EtCp)₃), tris(methylcyclopentadienyl) scandium (Sc(MeCp)₃), scandium chloride (ScCl₃), bis(ethylcyclopentadienyl) scandium chloride (ClSc(EtCp)₂), bis(methylcyclopentadienyl) scandium chloride (ClSc(MeCp)₂), bis(ethylcyclopentadienyl) (bis(dimethylamino)acetamidinato) scandium ((bdma)Sc(EtCp)₂), bis(ethylcyclopentadienyl)(ditertbutyltriazenido) scandium ((dbt)Sc(EtCp)₂), tris(2,2,6,6-tetramethyl-3,5-heptanedionato) scandium (Sc(TMHD)₃), and/or the like, or a mixture thereof. In some non-limiting embodiments, the scandium precursor may comprise bis(ethylcyclopentadienyl) scandium chloride (CISc(EtCp)₂).

In some non-limiting embodiments, the method 200 may further include a step 204 of purging the first precursor, such as a scandium precursor, from the internal volume 112 of the reactor 102. The purging 204 the first precursor step may include purging the first precursor from the internal volume 112 of the reactor 102 by injecting, such as continuously injecting, inactive gas into the internal volume 112 of the reactor 102, such as by injecting through the available gas injection ports 109, the process gas source 107 through the ICP source 103, and the gas dispersion arrangement 132. Non-limiting examples of inactive gases include Ar and N₂, and the like. The inactive gas flow through the gas injection ports 109, the process gas source 107 through the ICP source 103, and/or the has dispersion arrangement 132 is used to efficiently remove remaining precursor and/or reaction byproducts. In this regard, the first precursor is prevented from entering the reactor 102 after dosage, so that inactive gas can flow through the reactor 102 and remove excess first precursor. In some non-limiting embodiments, the method 200 may further include the step 204 of purging the first precursor, such as a scandium precursor, from the internal volume 112 of the reactor 102 for at least 0.1 s, or at least 1 s, or at least 5 s, or at least 10 s, or at least 15 s, or at least 20 s, or at least 25 s, or at least 30 s. The method 200 may further include the step 204 of purging the first precursor, such as a scandium precursor, from the internal volume 112 of the reactor 102 for up to 40 s, or up to 35 s, or up to 30 s, or up to 25 s, or up to 20 s. The time of purging the first precursor from the internal volume 112 of the reactor 102 is determined based on how long the valve 146 on the precursor vapor delivery arrangement 140a or the valve manifold 160 (i.e., the input valve 162 and the output valve 166) is closed, and/or the valve 176 on the MFC arrangement is closed, if present, after being open for dosage and before a valve for dosing the co-reactant is opened (i.e., the interval between closing one valve and opening another valve).

In some non-limiting embodiments, the method 200 may further include a step 206 of dosing the surface of the substrate 118 with a co-reactant. The dosing 206 of the surface of the substrate 118 with a co-reactant may be performed by at least one precursor vapor delivery arrangement 140a-b, an MFC arrangement as shown in FIG. 5C, and/or the ICP source 103. The precursor vapor delivery arrangement 140a-b for dosing the co-reactant may be the same precursor vapor delivery arrangement or different from the precursor vapor delivery arrangement used for dosing of the first precursor. For example, the apparatus 100 may include at least two precursor vapor delivery arrangements, which may include MFC arrangements, where one arrangement is for dosing the first precursor and the second arrangement is for dosing the co-reactant. In some non-limiting embodiments, the co-reactant may be ammonia (NH₃), hydrazine (N₂H₂), or a mixture thereof. In some non-limiting embodiments, the ALD may be thermal ALD. For example, the ALD may be thermal ALD and the co-reactant may be ammonia (NH₃), hydrazine (N₂H₂), or a mixture thereof. Alternatively, the co-reactant may be plasma. In some non-limiting embodiments, the ALD may be plasma-enhanced ALD (PEALD). For example, the ALD may be PEALD and the co-reactant may be plasma. In such an embodiment, the apparatus 100 may include at least one precursor vapor delivery arrangement 140a-b for dosing the first precursor and an ICP source 103 for dosing plasma, each of which may include MFC arrangements. The plasma species may include N₂, H₂, NH₃, N₂H₄, Ar and the like, and mixtures thereof (e.g., N₂—H₂, N₂—H₂—Ar, NH₃, NH₃—Ar, NH₃—N₂—H₂, NH₃—N₂—H₂—Ar, etc.). In some non-limiting embodiments, the method 200 of forming a film on a surface of a substrate includes the step 206 of dosing the surface of the substrate with a co-reactant for at least 0.01 s, or at least 1 s, or at least 5 s, or at least 10 s, or at least 15 s, or at least 20 s, or at least 25 s. The method 200 of forming a film on a surface of a substrate may include the step 206 of dosing the surface of the substrate with a co-reactant for up to 40 s, or up to 35 s, or up to 30 s, or up to 25 s, or up to 20 s, or up to 15 s, or up to 10 s. The time of dosage of the first precursor and co-reactant is determined based on how long the valve 146 of the precursor vapor delivery arrangement 140a or the valve manifold 160 on the precursor vapor delivery arrangement 140b (i.e., the input valve 162 and the output valve 166) is open, or similar valve/means on the ICP source 103 (such as on the process gas source 107), if plasma is used, and/or a valve 176 on an MFC arrangement is open, if present.

In some non-limiting embodiments, the method 200 may further include a step 208 of purging the co-reactant from the internal volume 112 of the reactor 102. The purging 208 the co-reactant step may include purging the co-reactant from the internal volume 112 of the reactor 102 by injecting, such as continuously injecting, inactive gas into the internal volume 112 of the reactor 102, such as by injecting through the available gas injection ports 109, the process gas source 107 through the ICP source 103, and/or the gas dispersion arrangement 132. The inactive gas flow through the gas injection ports 109, by the process gas source 107 through the ICP source 103, and/or the gas dispersion arrangement 132 is used to efficiently remove remaining co-reactant and/or reaction byproducts. In some non-limiting embodiments, the method 200 may further include the step 208 of purging the co-reactant from the internal volume 112 of the reactor 102 for at least 0.1 s, or at least 1 s, or at least 2 s, or at least 3 s, or at least 4 s, or at least 5 s, or at least 10 s, or at least 15 s, or at least 20 s. The method 200 may further include the step 208 of purging the co-reactant from the internal volume 112 of the reactor 102 for up to 30 s, or up to 25 s, or up to 20 s, or up to 15 s, or up to 10 s, or up to 5 s. The time of purging the co-reactant from the internal volume 112 of the reactor 102 is determined based on how long the valve 146 is closed on the precursor vapor delivery arrangement 140a, or the valve manifold (i.e., the input valve 162 and the output valve 166) is closed on the precursor vapor delivery arrangement 140b, or similar valve/means on the ICP source 103 (such as on the process gas source 107) if plasma is used, and/or a valve 176 on the MFC arrangement is closed if present, after dosing of the co-reactant, and before a valve to dose another precursor is opened (i.e., the interval between closing one valve and opening another valve).

In some non-limiting embodiments, the method 200 of forming a film may include forming a scandium nitride film on the surface of the substrate 118. For example, the method 200 of forming a film may include forming a single-crystal, cubic phase scandium nitride film on the surface of the substrate 118. The method 200 of forming a film may include forming a scandium nitride film by epitaxial growth. The method 200 of forming a film may include forming a scandium nitride film with impurity content of less than 10 atom %, or less than 5 atom %, or less than 4 atom %, or less than 3 atom %. The method 200 of forming a film may include forming a scandium nitride film with oxygen content of less than 1 atom %, or less than 0.8 atom %, or less than 0.6 atom %, or less than 0.5 atom %. The method 200 of forming a film may include forming a scandium nitride film with chlorine content of less than 10 atom %, or less than 5 atom %, or less than 4 atom %, or less than 3 atom %. The method 200 of forming a film may include forming a scandium nitride film with carbon content of less than 5 atom %, or less than 4 atom %, or less than 3 atom %, or less than 2 atom %. The method 200 of forming a film may include forming a scandium nitride film with a nitrogen-to-scandium ratio (N:Sc) in the range of from 10:1 to 1:10, or in the range of from 5:1 to 1:5, or in the range of from 3:1 to 1:3, or in the range of from 2:1 to 1:2, or approximately 1:1. The method 200 of forming a film may include forming a scandium nitride film at a growth-per-cycle (GPC) rate in the range of from 0.05 to 3 Å/cycle, or in the range of from 0.1 to 1 Å/cycle, or in the range of from 0.125 to 0.3 Å/cycles. The method 200 of forming a film may include forming a scandium nitride film with a thickness of at least 1 nm, or at least 5 nm, or at least 10 nm, or at least 15 nm, or at least 20 nm, or at least 25 nm, or at least 30 nm, or at least 35 nm, or at least 40 nm, or at least 45 nm, or at least 50 nm, or at least 100 nm. A scandium nitride film can be achieved using ALD by implementing the ALD process described herein.

The following Examples are presented to demonstrate the general principles of the invention of this disclosure. The invention should not be considered as limited to the specific examples presented.

### EXAMPLES

### Experimental Background

### Film Deposition

The films described in these Examples were formed using PEALD under ultra-high purity conditions. The depositions were performed in an ALD150LX perpendicular-flow reactor from the Kurt J. Lesker Company (Jefferson Hills, PA). The scandium precursor used was bis(ethylcyclopentadienyl) scandium chloride (ClSc(EtCp)₂), available from Dockweiler Chemicals GmbH (Marburg, Germany). This heteroleptic compound is a solid at room temperature, with a melting point at 95° C. ClSc(EtCp)₂ was contained in a stainless steel flow-ampoule and kept at 180° C. to develop adequate vapor pressure for delivery. The vapor pressure was approximately 0.2 Torr. The process gases used were Ar, N₂ (99.999%, Airgas), and H₂ (99.999%, Linde). Scandium nitride films were grown by PEALD at a substrate temperature from 200-300° C. using ClSc(EtCp)₂ and a mixture of N₂ and H₂ (N₂—H₂) plasma species as reactants.

The dose of CISc(EtCp)₂ is defined as the amount of time the associated ALD valves on the “in” and “out” sides of the flow-through ampoule were held open, using a precursor vapor delivery arrangement such as that shown in FIG. 5B. During CISc(EtCp)₂ dose and exposure steps, a downstream butterfly valve, i.e., the throttle valve 129 of FIG. 4, was used to limit conductance between the reactor and pump, thereby increasing the pressure and Sc precursor residence time inside the reactor. N₂—H₂ plasma was generated at ˜0.3 Torr by a remote inductively coupled plasma (ICP) source operating at 13.56 MHz frequency and 600 W plasma power. The plasma gas flow rates were 40 sccm N₂ and 5 sccm H₂ (8:1), which was established by an MFC arrangement as shown in FIG. 5C. The reactor pressure was maintained at ˜1 Torr during ClSc(EtCp)₂ and N₂—H₂ plasma purge steps. ScN films were grown on silicon (Si), sapphire (Al₂O₃) and magnesium oxide (MgO) substrates; more specifically, untreated 150 mm Si (100), 50 mm Al₂O₃ (0001) and 1 cm×1 cm MgO (001) substrates.

### Testing Background

### Ellipsometry and X-Ray Reflectivity (XRR)

Scandium nitride film thickness and optical properties were determined ex situ by spectroscopic ellipsometry (SE) using a M-2000 spectroscopic ellipsometer, available from J. A. Woollam (Lincoln, Nebraska), over a range of wavelengths from 193-1000 nm. Ellipsometry measurements were also performed in situ during scandium nitride film growth using a FS-8 multi-wavelength ellipsometer, available from Film Sense (Lincoln, Nebraska), providing eight wavelengths of ellipsometric data (367 nm, 449 nm, 526 nm, 594 nm, 656 nm, 735 nm, 852 nm, and 949 nm). In both cases, a Cauchy model was used to determine the scandium nitride film thickness and the refractive index. To avoid the effects of direct band gap absorption when modeling the ellipsometric data, the fitted data were limited to wavelengths of greater than or equal to 526 nm.

A X'Pert³ MRD x-ray diffractometer, available from Malvern Panalytical (Malvern, United Kingdom), was used to obtain x-ray reflectivity (XRR) measurements in order to confirm the film thickness measured by ellipsometry.

### X-Ray Photoelectron Spectroscopy (XPS)

The film composition was measured by depth profile x-ray photoelectron spectroscopy (XPS) using a VersaProbe III instrument, available from Physical Electronics (Chanhassen, Minnesota) equipped with a monochromatic Al kα x-ray source (1486.6 eV) and a concentric hemispherical analyzer. Quantification utilized instrumental relative sensitivity factors (RSFs) that account for the x-ray cross section and inelastic mean free path of the electrons. For the major elements (Sc, N), the 1σ quantitative accuracy is expected to be within ±10 rel %. Due to poor counting statistics, and finite background levels of C and O, the 1σ accuracy is expected to be within ±20-40 rel % for the minor elements. Ion sputtering was accomplished using a 2 kV Ar⁺ ion beam. Since detection of low levels of C and O were of interest, films were evacuated to <2×10⁻⁹ Torr prior to starting measurements. C and O were acquired first in the depth profile to minimize any re-adsorption of C- and O-containing gases from the residual gases in the XPS chamber. This resulted in a lower limit of detection for both elements of ˜0.1-0.2 at. %.

### X-Ray Diffraction (XRD)

The structural phase of as deposited ScN was investigated by grazing incidence x-ray diffraction (GIXRD) using an Empyrean diffractometer, available from Malvern Panalytical (Malvern, United Kingdom). Out-of-plane XRD and phi-scans were performed using Rigaku (Tokyo, Japan) Smartlab and Malvern Panalytical (Malvern, United Kingdom) Empyrean diffractometers, respectively.

### Field Emission Scanning Electron Microscopy (FESEM)

To evaluate 3-D conformality, silicon trenches with a 1:4 aspect ratio were fabricated by deep reactive ion etching (RIE) and subsequently coated with silicon nitride. The sample was then sectioned by edge cleaving and focused ion beam milling with a Scios 2 DualBeam, available from Thermo Scientific (Waltham, MA), and finally imaged using a Gemini 500 field emission scanning electron microscope, available from Zeiss (Oberkochen, Germany). Silicon nitride deposited on planar Si was also imaged to investigate film morphology.

### Hall Probe

ScN electrical properties were investigated using 4-probe, 300×300 μm Hall bar patterns fabricated on both ScN/Al₂O₃ and ScN/MgO. Contact pads were fabricated of 20 nm Pd followed by 50 nm Au. The Hall resistance was measured using a current of 1 mA and with the magnetic field swept from negative-to-positive 2900 Gauss, with the data demonstrating highly linear behavior. For each sample, five devices were measured with average results provided in Table 3.

### Deposition Results

### Film Development

Scandium nitride films were measured in real-time during growth by in situ multi-wavelength ellipsometry (MWE) to assist in the development of the scandium nitride PEALD process. The thickness and index of the evolving scandium nitride film were determined using an ellipsometric model consisting of a silicon substrate, native oxide layer, and Cauchy-ScN layer. ScN growth-per-cycle (GPC) vs. ClSc(EtCp)₂ precursor dose time was investigated on untreated 150 mm Si (100) substrates to determine the dose saturation behavior of the PEALD process at substrate temperatures ranging from 200-300° C.

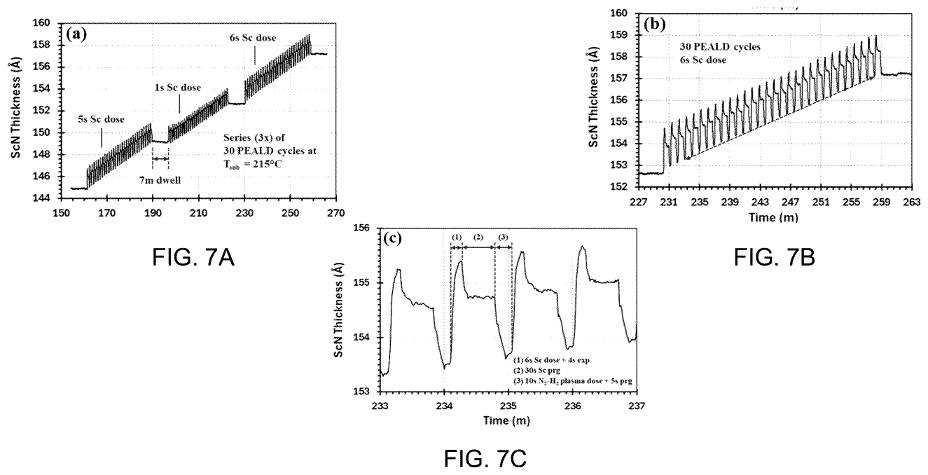

The method used to generate this data is as follows. For each of the investigated substrate temperatures, a design-of-experiments (DOE) was carried out on a single-pristine 150 mm Si (100) substrate, whereby 30 PEALD cycles were performed for each of the evaluated ClSc(EtCp)₂ precursor dose times. For example, FIG. 7A shows a series of 30 PEALD cycles corresponding to 5, 1, and 6 s ClSc(EtCp)₂ precursor dose times at 215° C. substrate temperature. Note that a ScN base-layer (˜10 nm thick) was first deposited by PEALD on a bare Si (100) substrate in situ to mitigate any subsequent nucleation delay associated with the silicon native oxide surface. The order of the 30-cycle depositions in FIG. 7A is randomized with respect to dose time to further ensure that no artifacts related to the experimental method affected the reported GPC values. To normalize process conditions as well as provide a separation in the data for subsequent analysis, each 30-cycle deposition is separated by a 7-minute dwell time under inert gas flow and repeated 3× for reproducibility. The dose times investigated ranged from 0.5-7 s, where ScN GPC values were determined from the slope of the corresponding growth profiles as illustrated in FIG. 7B.

For this investigation, the Sc precursor exposure and purge times remained fixed at 4 and 30 s; and the N₂—H₂ plasma dose and purge times were fixed at 10 and 5 s, respectively. The MWE data were subsequently analyzed using the following three-layer ellipsometric model: (1) Si substrate (at growth temperature), (2) native oxide layer and (3) Cauchy-ScN layer. The native oxide thickness was determined prior to the ScN base-layer growth. This model was used to determine the total ScN thickness and the refractive index at dwell times between each 30-cycle deposition. The corresponding index ranged between 2.14 and 2.62 at 200° C. and 300° C., respectively. Index values were then used to fit each preceding 30 cycle growth profile and extract the GPC based on slope. The slope indicated in FIG. 7B corresponds to the ScN growth rate. GPC is obtained by multiplying the growth rate by the ScN PEALD cycle time. Finally, FIG. 7C identifies the general features of the PEALD ScN step profile determined by MWE for a 6 s Sc precursor dose.

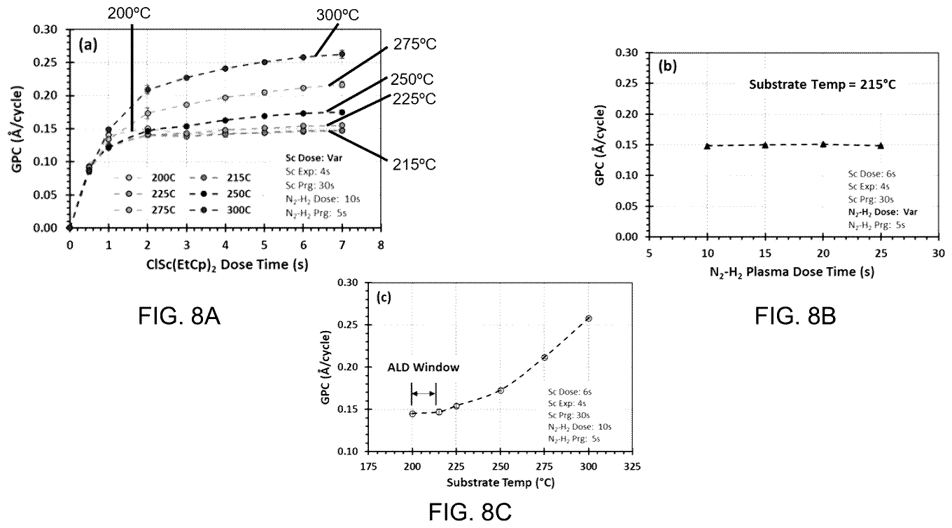

ClSc(EtCp)₂ dose saturation curves are presented in FIG. 8A, where each datapoint represents the average of three identical ScN depositions (error bars included). As observed in FIG. 8A, the GPC saturates at ˜0.15 Å/cycle with increasing CISc(EtCp)₂ dose time at 200° C. and 215° C. Similar saturation behavior is seen at 225° C. with increasing CISc(EtCp)₂ dose time, but the GPC is slightly higher. This behavior is also observed in FIG. 8C, where the GPC at 215° C. also shows a very slight increase compared to the GPC measured at 200° C. At substrate temperatures above 225° C., non-saturation becomes more evident with increasing dose time, along with more significant changes in the overall GPC with increasing substrate temperature as demonstrated in FIGS. 8A and 8C. As identified in FIG. 8C, these results indicate that an ALD window exists between 200-215° C. substrate temperature. At temperatures ≥225° C., the continued increase in GPC with ClSc(EtCp)₂ dose time and/or substrate temperature are indicative of pyrolysis of the Sc precursor.

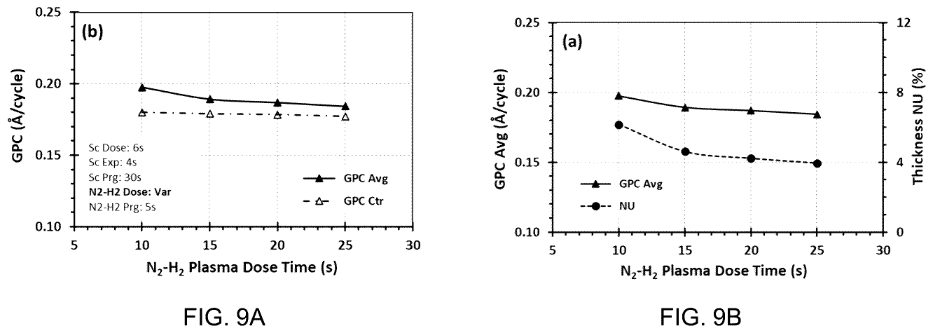

The N₂—H₂ plasma dose saturation curve presented in FIG. 8B shows no variation in the GPC between 10 and 25 s dose time, indicating that a 10 s plasma dose is sufficient to achieve saturation in the center of the reactor. SE measurements performed ex situ, however, revealed that ScN thickness uniformity across 150 mm Si substrates was improved by increasing the N₂—H₂ plasma dose time (see FIG. 9A-B).

Specifically, SE measurements were carried out ex situ to investigate N₂—H₂ plasma dose saturation across untreated 150 mm Si (100) substrates. GPC averages shown in FIG. 9A-B correspond to the thickness averages divided by the number of PEALD cycles. Compared to average values, the ScN GPC determined at the center of the substrate remained constant with N₂—H₂ plasma dose time as shown in FIG. 9A. The data shown in FIG. 9B demonstrates that film thickness NU is reduced by increasing the N₂—H₂ plasma dose time. Due to accelerated growth observed during the initial nucleation & growth phase of ScN PEALD on native Si oxide, the GPC determined ex situ is higher in FIGS. 9A-B compared to values reported for in situ measurements (e.g., see FIG. 8B).

Based on these results, a 20 s N₂—H₂ plasma dose was utilized for all subsequent ScN depositions. The following process parameters were used to grow thicker PEALD ScN at 215° C. for subsequent characterization: CISc(EtCp)₂ dose=6 s, ClSc(EtCp)₂ exposure=4 s, CISc(EtCp)₂ purge=20 s, N₂—H₂ plasma dose=20 s and N₂—H₂ plasma purge=5 s (cycle time=55 s).

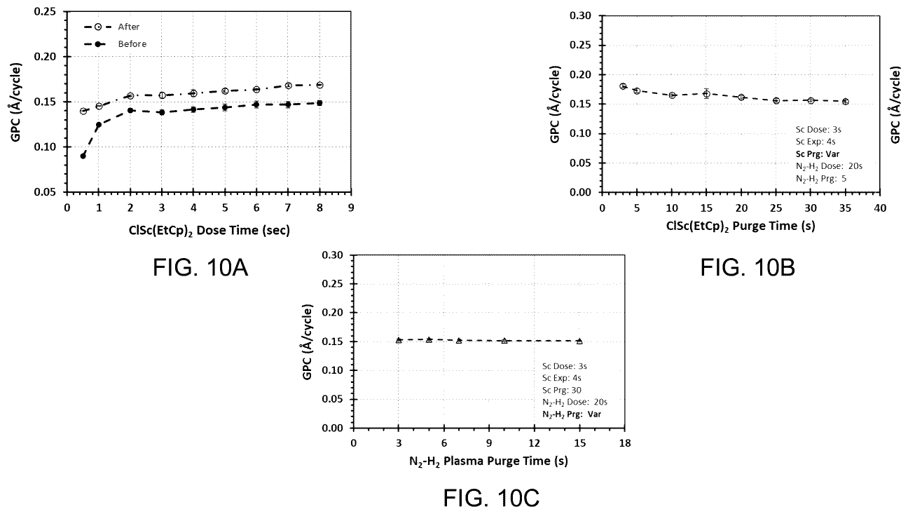

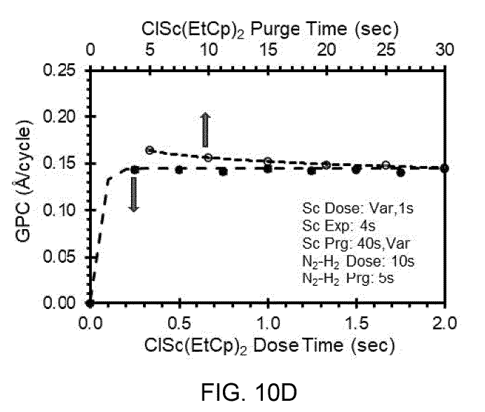

It is noted here some anomalous behavior was observed of the CISc(EtCp)₂ precursor after aging and thermal cycling. Specifically, following a thermal cycling between 180° C. and room temperature of the chemical reservoir containing the Sc precursor, an approximately 12% increase in the GPC was observed at a substrate temperature of 215° C. This increase was compared to the same process carried out under identical conditions prior to the thermal cycling event. The modified CISc(EtCp)₂ dose saturated at 3 s and yielded a 0.16 Å/cycle GPC, and experienced a slight 0.01 Å/cycle increase in GPC when the dose was increased to 8 s (see FIG. 10A), matching similar trends observed in the original dose saturation curves (see FIG. 8A).

To explain the increased GPC, we evaluated the effect of purge time to observe potential parasitic effects of precursor overlap during the dose sequence. No change in GPC was observed for CISc(EtCp)₂ precursor purge times ≥25 s, while the N₂—H₂ purge time had no observed effect on the GPC between the entire tested range from 3-15 s (see FIGS. 10B-C). Subsequent investigation revealed dose saturation of the Sc precursor occurred at significantly shorter dose times indicative of improved CISc(EtCp)₂ delivery after the thermal cycling event (FIG. 10D). We concluded that at least one of the manual isolation valves on the flow-through ampoule was in a partially closed position prior to thermally cycling, thereby limiting the conductance through the ampoule.

### Film Properties Analysis

For optical, compositional and structural analysis, ScN films were deposited on untreated 150 mm Si (100) substrates using the PEALD process parameters defined above. Nominal film thicknesses for x-ray characterization were 25 nm and 40 nm. The average SE thicknesses determined ex situ for ScN #1 (XPS sample) and ScN #2 (XRR, GIXRD sample) were 25.4 and 41.9 nm, respectively. A thicker film was deposited for GIXRD to improve the measurement signal-to-noise ratio. For both samples, the thickness non-uniformity (NU) was <±4% (1σ) and the refractive index (at 633 nm wavelength) was 2.3 with NU<±3% (1σ). The refractive index NU was primarily due to a higher value in the center vs. towards the outer diameter of the substrate. To confirm the SE thickness, XRR measurements were also performed at the substrate center and edge positions of ScN #2. The SE center and edge thicknesses were 40.6 and 42.3 nm; and the XRR center and edge thicknesses were 39.7 and 41.8 nm, respectively. These results demonstrate good agreement between the two measurement techniques. XRR also revealed a higher mass density at the center vs. edge positions as follows: ρ_{ctr}=3.84 g/cm³ and ρ_{edge}=3.78 g/cm³. The density values reported here are lower than the reported bulk value of 4.264 g/cm³ for single-crystal, cubic-phase ScN.

Higher mass density measured in the center is likely due to geometric factors during ScN growth that result in a higher plasma density and/or UV light emission from the ICP source centered above the substrate surface. The 1.6% increase in density at the center, however, does not fully account for the 5% increase in the refractive index observed for ScN #2, where n_{ctr}=2.40 and n_{edge}=2.28. To better understand this increase, the optical properties were more thoroughly investigated ex situ by SE at the center and edge positions of ScN #1 and ScN #2. A direct bandgap at ˜2.45 eV was determined for both films at the center and edge positions, which is in good agreement with reported values in the literature.

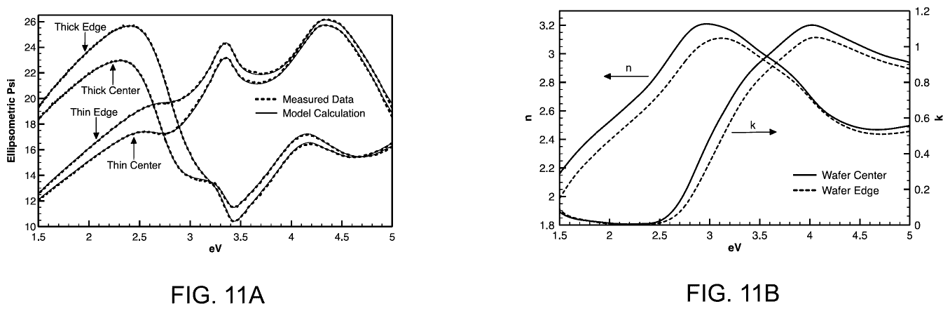

A detailed description of the measurements and the corresponding analysis is as follows. To characterize the film and overlayer thickness of ScN by PEALD, SE data were measured and analyzed over a 1.5-5 eV spectral range. Ellipsometric Psi spectra (4×) are plotted in FIG. 11A, corresponding to measurements on two ScN coated 150 mm Si (100) substrates identified as thin film (ScN #1) and thick film (ScN #2). These measurements were performed at two positions located at the center and edge of each substrate. As expected, large differences in the spectra are observed between the thin and thick films. However, significant discrepancies are also observed between the center and edge measurements. These discrepancies cannot be accounted for by simply varying the film and overlayer thicknesses in the analysis model, and suggest that the optical constants of the ScN films are significantly different between the center and edge of the substrate. To determine the ScN optical constants at the center, a multi-sample analysis was performed using the thin and thick film data sets acquired at the center of the substrate. Likewise, a multi-sample analysis was performed with the thin and thick film data sets acquired at the edge of the substrate.

Excellent SE data fits were achieved, as seen in FIG. 11A where the model calculated curves (solid lines) lie essentially on top of the measured data (dashed lines). The good fit is also quantified by the low MSE values shown in Table 1, which also reports the resulting film and overlayer thickness values. The determined ScN optical constant spectra are shown in FIG. 11B. For both spectra, an indirect bandgap is observed at ˜2.45 eV, which is agreement with previously reported values. The general shape and critical point features are also in agreement with previously published spectra, as is the increase in “k” below the bandgap (which may in part be due to free carrier “Drude” absorption). The amplitudes of the n & k spectra are significantly lower at the edge of the wafer. However, the “edge” spectra cannot be calculated by simply mixing “void” with the “center” spectra (using the Bruggeman effective medium approximation); therefore, the change in the optical constants is not simply due to a density or porosity change in the film. A follow up investigation of this phenomenon determined that the index NU correlated with continuous H₂ flow through the ICP source during ScN growth.

TABLE 1
Film thickness data

| | ScN Film | Overlayer | | Multi- |
|---|---|---|---|---|
| | Thickness | Thickness | Index at | Sample |
| Data Sets | (Å) | (Å) | 633 nm | Fit MSE |
| Thin, Center of Wafer | 226.3 | 32.6 | 2.50 | 1.727 |
| Thick, Center of Wafer | 374.2 | 56.4 | | |
| Thin, Edge of Wafer | 230.3 | 33.7 | 2.37 | 1.594 |
| Thick, Edge of Wafer | 390.1 | 57.1 | | |

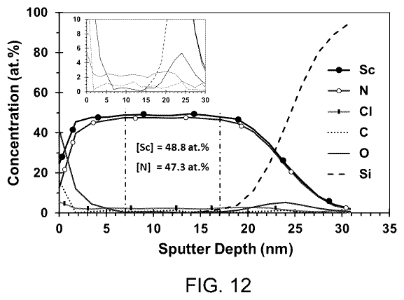

The XPS depth profile for ScN #1 is shown in FIG. 12, which contains the concentration vs. sputter depth of all major (Sc, N) and minor (Cl, C, O) components of the film. To determine the sputter depth, the SE thickness was used to convert sputter time to sputter depth. The high O and C impurity levels observed at the film surface are due to atmospheric exposure. As the Ar⁺ ions are used to sputter down into the bulk of the film, impurity levels decrease until a steady-state concentration is obtained. The native oxide interface is observed at ˜24 nm, and by 30 nm depth the bulk Si substrate is reached. Bulk concentrations for ScN were determined by averaging each elemental component between 7-17 nm sputter depth, as identified in FIG. 12. The film is slightly Sc rich containing 48.8±0.5 at. % Sc and 47.3±0.4 at. % N (N:Sc=0.97±0.01). Impurities are also present in the bulk of the film including 2.3±0.2 at. % Cl, 0.9±0.3 at. % C and 0.4=0.2 at. % O. The reported uncertainties represent the ±1σ variation associated with at. % averages over the specified range (i.e., 7-17 nm sputter depth).

XPS was also performed on a sample taken from the edge of ScN #1, which showed a consistent composition with the substrate center as follows: 48.4±0.4 at. % Sc, 47.4=0.4 at. % N, 2.6±0.1 at. % Cl, 0.9±0.2 at. % C and 0.3±0.2 at. % O. The N-to-Sc ratio in this case is slightly higher (N:Sc=0.98±0.01), but within the estimated uncertainty. A summary of the XPS results are presented in Table 2. At both center and edge positions, the bulk O content measured was just above the detection limit of the instrument. When compared to other nitrides such as TiN, it has been shown that ScN films (grown by reactive magnetron sputtering techniques) are more highly susceptible to oxygen contamination. To deposit ScN with high crystalline and electrical quality, it was concluded that UHV or other environments containing low amounts of oxygen are required. The results presented in FIG. 12 demonstrate that UHP conditions provide a suitable environment for the growth of ScN by PEALD techniques.

TABLE 2
XPS depth profile results for ScN film composition

| Position | Sc (at. %) | N (at. %) | N:Sc | Cl (at. %) | C (at. %) | O (at. %) |
|---|---|---|---|---|---|---|
| Center | 48.8 ± 0.5 | 47.3 ± 0.4 | 0.97 ± 0.01 | 2.3 ± 0.2 | 0.9 ± 0.3 | 0.4 ± 0.2 |
| Edge | 48.4 ± 0.4 | 47.4 ± 0.4 | 0.98 ± 0.01 | 2.6 ± 0.1 | 0.9 ± 0.2 | 0.3 ± 0.2 |

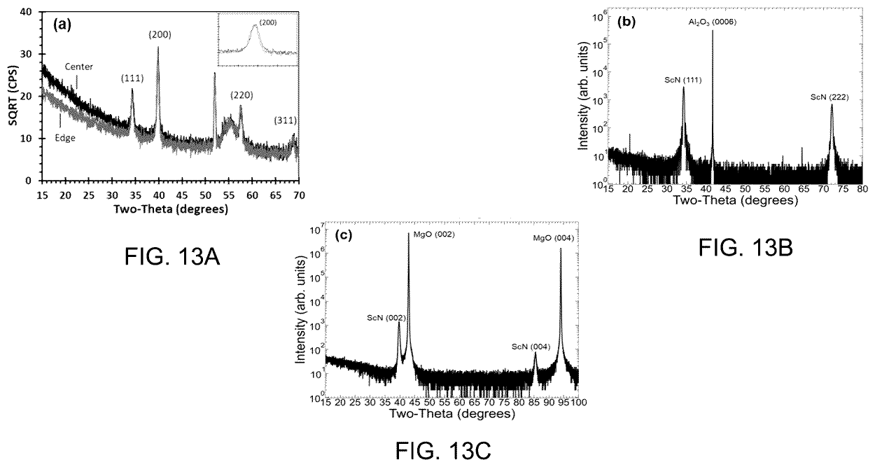

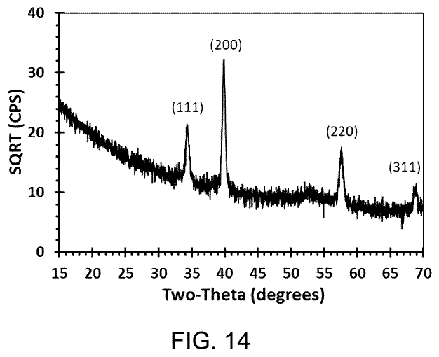

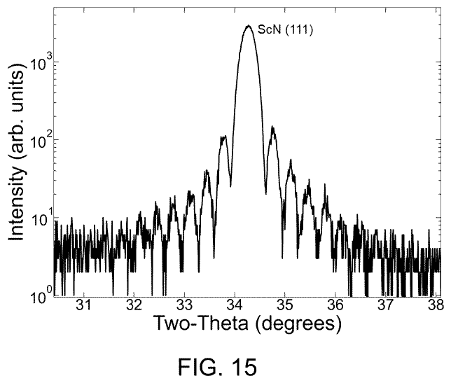

The GIXRD patterns for ScN #2 presented in FIG. 13A show (111), (200), (220) and (311) reflections matching cubic-phase ScN (PDF 04-001-1145). The narrow peak at ˜52° and broad peak at ˜55° are artifacts of the GIXRD method stemming from the Si substrate. These features can be eliminated and/or suppressed by rotating the substrate (see FIG. 14). Similar GIXRD patterns are observed at the center and edge positions indicative of a uniform, polycrystalline, cubic-phase structure across the 150 mm Si (100) substrate. ScN films were also deposited on Al₂O₃ (0001) and MgO (001) substrates for structural analysis, where out-of-plane XRD scans were performed to investigate signs of epitaxial growth. For ScN grown on Al₂O₃ (0001), the XRD pattern in FIG. 13B shows (111) and (222) reflections consistent with single-crystal, cubic-phase ScN. Based on the interference pattern observed for the (111) peak (see FIG. 15), the ScN film thickness was estimated at 45 nm.

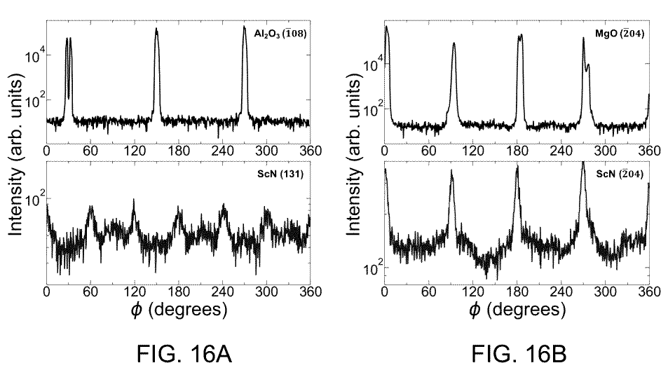

The XRD pattern for ScN deposited on MgO also indicates single-crystal, cubic-phase ScN; with the (002) and (004) reflections of the ScN film matching the underlying MgO substrate as shown in FIG. 13C. Given that both ScN and MgO crystallize in a cubic rock-salt phase (Fm3̅m), the ScN is likely grown epitaxially to the underlying MgO substrate giving rise to the shared out-of-plane (001) orientation. Based on the (002) and (004) peak positions of ScN, the out-of-plane lattice constant displays a slight elongation with α₀=4.54 Å as compared to the bulk value of α₀=4.50 Å. This is likely due to the compressive epitaxial strain imposed by the MgO substrate. When ScN is grown on the Al₂O₃ (0001) substrate, shown in FIG. 13B, the rhombohedral structure (R3̅c) displays epitaxial lattice matching with the three-fold symmetry of the cubic (111) plane forcing the observed (111) out-of-plane orientation. Additionally, based on the ScN (111) and (222) peak position, α₀=4.53 Å, slightly larger than the expected bulk value. Furthermore, phi-scans were performed (see FIGS. 16A-B) to examine the in-plane rotational symmetries and confirm the single-crystal epitaxial growth of ScN on MgO (001) and Al₂O₃ (0001). Both show the expected in-plane symmetries, with ScN on Al₂O₃ showing 6-fold symmetry due to the underlying hexagonal structure of the sapphire substrate; and ScN on MgO showing a 4-fold symmetry due to the shared cubic structure.

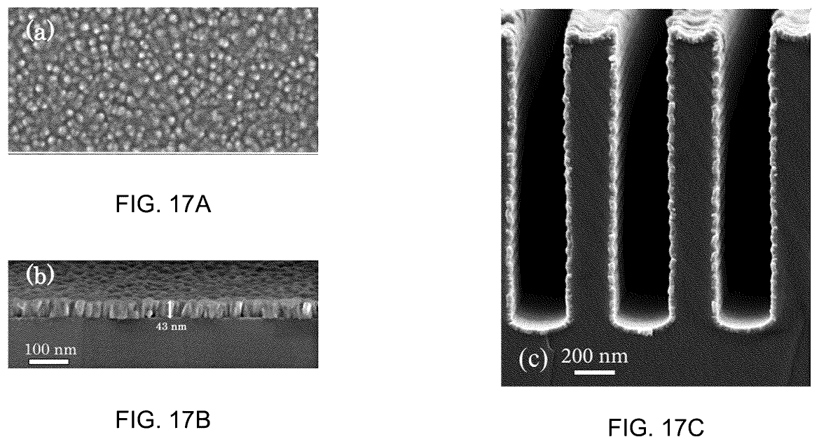

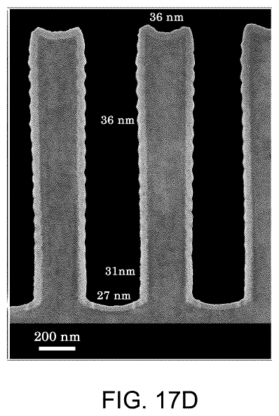

FESEM images in FIG. 17A provides a top-view and FIG. 17B provides a cross-sectional view taken from the center position of ScN #2, where columnar grains with sizes ranging from 16-28 nm are observed. Film thickness is estimated at 43 nm, which provides good agreement with the average SE thickness of 41.9 nm reported above. Film conformality was also examined by depositing ScN over 4:1 aspect ratio trench structures shown in FIG. 17C. These trenches were fabricated by RIE, where the opening measures 312 nm; the corresponding depth is 1.29 μm. The ScN film conformed well to the undulated etched Si surface, achieving a thickness of 36 nm on the top and 27 nm at the bottom of the trenches, resulting in a bottom-to-top thickness ratio of 75% (see FIG. 17D). Since the mean free path of the gas/vapor species in the reactor is more than two orders-of-magnitude larger than the trench width, the variation in thickness observed in FIG. 17C can be attributed to the ballistic transport and reaction kinetics of precursor gases/vapors, particularly plasma species, within the narrow confines of the trench structures. No attempt was made to optimize the ScN PEALD process (such as significantly increasing dose times) for improving coverage across the high aspect ratio (HAR), nm-scale features.

Electrical properties were also evaluated for the ScN films deposited on Al₂O₃ (0001) and MgO (001) substrates represented by FIG. 13B and FIG. 13C, respectively. ScN was deposited concurrently on both substrates, along with the HAR substrate shown in FIG. 17C. A small (˜2 cm×2 cm) Si (100) substrate was also included as a witness sample. Film thickness determined by SE on the Si witness sample was 34.3 nm (index=2.39), which provides good agreement with the 36 nm ScN thickness measured by FESEM at the top of the HAR trench structures (see FIGS. 17C-D). However, the film thickness determined by interference fringes observed for ScN on Al₂O₃ (0001) described above (see FIG. 15), indicate 45 nm Sc thickness. This suggests a higher GPC for single-crystal vs. polycrystalline cubic-phase ScN by PEALD. Hall measurements were subsequently performed to determine average values for ScN resistivity, mobility and carrier concentrations. A summary of these results are presented in Table 3.

TABLE 3
Hall measurement results for ScN

| Substrate | Resistivity | Mobility | Carrier Conc. |
|---|---|---|---|
| Material | (mΩ · cm) | (cm²/Vs) | (cm⁻³) |
| Al₂O₃ (0001) | 13.9 | 23.5 | 2.36 × 10¹⁹ |
| MgO (001) | 1.01 | 298.0 | 2.35 × 10¹⁹ |

Density functional theory (DFT) calculations by Deng et al., Optical and transport measurement and first-principles determination of the ScN band gap, Phys. Rev. B, 91, 045104 (2015), predicted a direct band gap at 2.02 eV for intrinsic cubic-phase ScN. High quality ScN epilayers grown by HVPE, with very low levels of impurities, were reported by Oshima et al., Epitaxial growth of phase-pure ε-Ga₂O₃ by halide vapor phase epitaxy, J. Appl. Phys., 115, 153508 (2014), where the direct band gap was measured at 2.06 eV. This measured band gap is in good agreement with the calculated value of 2.02 eV by Deng. Free electron concentrations, however, ranged from 10-18 to 10-20 cm⁻³ for nominally undoped ScN films. These carrier concentrations could not be attributed to impurities but could be related to native point defects (e.g., nitrogen vacancies) in the bulk of the ScN film. The results of the study by Deng also showed that for epitaxial layers grown by reactive magnetron sputtering, the direct band gap increased between 2.18-2.7 eV with increasing carrier concentration ranging from 1.12-12.8×1020 cm⁻³, respectively. The increase in the band gap and free electron concentration were attributed to an increase in fluorine (F) impurities serving as n-type donors. Film composition measured by Auger electron spectroscopy (AES) and XPS determined that F impurity levels ranged from below the AES-XPS detection limit to 3 at. % F. A similar relationship between the direct band gap and carrier concentration was observed by Moram et al., The effect of oxygen incorporation in sputtered scandium nitride films, Thin Solid Films, 516, 8569-8572 (2008), but the increase was attributed to O impurities. In this case, the direct band gap increased between 2.2 and 3.1 eV with carrier concentrations ranging from 1021 and 1022 cm⁻³, respectively. The effect of F, O, H and tantalum (Ta) impurities on carrier concentration in bulk cubic-phase ScN was theoretically investigated by Kumagai et al., Point Defects and p-Type Doping in ScN from First Principles, Phys. Rev. Appl., 9, 034019 (2018), which showed that these elements act as either single (O) or double n-type donors (H, F, Ta).

For PEALD ScN, the measured carrier concentrations reported in Table 3 are significantly lower than the values reported by Deng and Moram described above. However, these values are consistent with those reported by Oshima for high quality ScN epilayers grown by HVPE with very low levels of impurities. For ScN deposited epitaxially on MgO (001) by PEALD, the measured mobility of 298 cm²/Vs is also consistent with the mobility reported by Oshima at 284 cm²/Vs for films grown by HVPE on m-plane sapphire. The higher mobility reported here could be explained by the MgO (001) substrate providing a more ideal ScN growth template vs. m-plane sapphire.

### Investigation Summary

For ScN grown at 215° C. on Si (100), XPS depth profiling showed the film was slightly Sc rich containing 48.6 at. % Sc and 47.4 at. % N (N:Sc=0.97). Impurities were also present in the bulk of the film including 2.5 at. % Cl, 0.9 at. % C and 0.4 at. % O. The oxygen content measured was just above the detection limit of the XPS instrument. GIXRD measurements produced (111), (200), (220) and (311) reflections matching polycrystalline, cubic-phase ScN. For XPS and GIXRD, center and edge positions were measured on 150 mm Si substrates where similar results were obtained, thereby confirming ScN composition and structure across the wafer (elemental concentrations defined above are averages corresponding to the center and edge positions).

FESEM images revealed columnar grains with sizes ranging from 16-28 nm. ScN conformality across 4:1 aspect ratio trench structures was also imaged by FESEM which showed a bottom-to-top thickness ratio of 75%. Out-of-plane x-ray diffraction patterns indicated single-crystal, cubic-phase ScN deposited at 215° C. on sapphire (0001) and magnesium oxide (001) substrates; phi-scans confirmed epitaxial growth. ScN electrical properties were evaluated by performing Hall measurements to determine mobility, free electron concentration and resistivity. For ScN PEALD on magnesium oxide (001), the average mobility was 298 cm²/Vs with a carrier concentration of 2.35×10¹⁹ cm⁻³. The average resistivity was 1.01 mΩ·cm.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

The invention claimed is:

1. A method of forming a film on a surface of a substrate in an internal volume of a reactor, comprising:
dosing the surface of the substrate with a scandium precursor;
purging the scandium precursor from the internal volume of the reactor;
dosing the surface of the substrate with a co-reactant; and
purging the co-reactant from the internal volume of the reactor.

2. The method of claim 1, wherein the co-reactant is plasma comprising N₂, H₂, NH₃, N₂H₄, Ar, or a mixture thereof.

3. The method of claim 1, wherein the co-reactant is ammonia (NH₃), hydrazine (N₂H₄), or a mixture thereof.

4. The method of claim 1, wherein the scandium precursor comprises Sc(Cp)₃, Sc(EtCp)₃, Sc(MeCp)₃, ScCl₃, ClSc(EtCp)₂, ClSc(MeCp)₂, (bdma)Sc(EtCp)₂, (dbt)Sc(EtCp)₂, Sc(TMHD)₃ or a combination thereof.

5. The method of claim 1, wherein the substrate comprises silicon, germanium, sapphire, magnesium oxide, boron nitride, aluminum nitride, gallium nitride, or indium nitride, or a combination thereof.

6. The method of claim 1, further comprising heating the substrate to a temperature in the range of from 100° C. to 400° C.

7. The method of claim 6, further comprising heating the substrate to a temperature in the range of from 200° C. to 215° C.

8. The method of claim 1, wherein the forming step comprises forming a single-crystal, cubic phase scandium nitride film on the surface of the substrate.

9. The method of claim 1, wherein the forming step comprises forming epitaxial cubic phase scandium nitride film on the surface of the substrate.

10. The method of claim 1, further comprising positioning the substrate in the internal volume of the reactor under ultra-high purity conditions.

11. The method of claim 1, wherein the forming step comprises forming a scandium nitride film comprises less than 0.5 atom % oxygen content.

12. An apparatus for atomic scale processing, comprising:
a reactor having inner and outer surfaces, wherein at least a portion of the inner surfaces define an internal volume of the reactor;
a fixture assembly positioned within the internal volume of the reactor having a surface configured to hold a coated substrate within the internal volume of the reactor;
a scandium precursor dosage source comprising a scandium precursor; and
a co-reactant dosage source comprising a co-reactant.

13. The apparatus of claim 12, wherein the co-reactant dosage source is an inductively coupled plasma source.

14. The apparatus of claim 13, wherein the co-reactant comprises plasma comprising N₂, H₂, NH₃, N₂H₄, Ar, or a mixture thereof.

15. The apparatus of claim 12, wherein the co-reactant comprises ammonia (NH₃), hydrazine (N₂H₄), or a mixture thereof.

16. The apparatus of claim 12, wherein the scandium precursor comprises Sc(Cp)₃, Sc(EtCp)₃, Sc(MeCp)₃, ScCl₃, ClSc(EtCp)₂, CISc(MeCp)₂, (bdma)Sc(EtCp)₂, (dbt)Sc(EtCp)₂, Sc(TMHD)₃ or a combination thereof.

17. The apparatus of claim 12, wherein the coated substrate comprises:
a substrate; and
a scandium nitride film over a surface of the substrate.

18. The apparatus of claim 17, wherein the substrate comprises silicon, germanium, sapphire, magnesium oxide, boron nitride, aluminum nitride, gallium nitride, indium nitride or a combination thereof.

19. The apparatus of claim 17, wherein the scandium nitride film comprises single-crystal, cubic phase scandium nitride.

20. The apparatus of claim 17, wherein the scandium nitride film comprises epitaxial, cubic phase scandium nitride.

21. The apparatus of claim 17, wherein the scandium nitride film comprises less than 0.5 atom % oxygen content.

22. The apparatus of claim 12, wherein the substrate is heated to a temperature in the range of from 100° C. and 400° C.
